(19) United States
(12) Patent Application Publication
(10) Pub. No.: US 2020/0045832 A1
(43) Pub. Date: Feb. 6, 2020

(54) 3D PRINTING METHOD AND PRODUCT

(71) Applicant: SIGNIFY HOLDING B.V., EINDHOVEN (NL)

(72) Inventors: RIFAT ATA MUSTAFA HIKMET, EINDHOVEN (NL); TIES VAN BOMMEL, HORST (NL)

(21) Appl. No.: 16/339,046

(22) PCT Filed: Oct. 2, 2017
(86) PCT No.: PCT/EP2017/074990

§ 371 Date: Apr. 3, 2019

(30) Foreign Application Priority Data
Oct. 4, 2016 (EP) 16192224.0

(51) Int. Cl. H05K 3/28; H05K 1/02; H05K 1/18; B33Y 80/00

(52) U.S. Cl. CPC H05K 3/284; H05K 1/0284; H05K 1/18; B33Y 10/00; H05K 2201/10106; H05K 2201/2054; H05K 2201/2072; B33Y 80/00

(57) ABSTRACT

A product and a method of manufacturing a product are provided, in which a 3D structure (26) is printed over a printed circuit board (20). An adhesion layer (24) is provided between them. One of the interfaces to the adhesion layer (24) comprises a cavity structure (22). This improves adhesion and releases stress build up in the printed circuit board (20).

### FIELD OF THE INVENTION

This invention relates to 3D printing, and in particular printing a structure over a printed circuit board.

### BACKGROUND OF THE INVENTION

Digital fabrication is set to transform the nature of global manufacturing.

One aspect of digital fabrication is 3D printing. The most widely used 3D printing process is Fused Deposition Modeling (FDM).

FDM printers use a thermoplastic filament, which is heated to its melting point and then extruded, layer by layer, to create a three dimensional object. FDM printers are relatively fast, low cost and can be used for printing complicated 3D objects.

Such printers may be used for printing various shapes using various polymers. The technique is also being further developed for the production of LED luminaires and lighting solutions.

One trend is for the integration of electronics into 3D printed structures. For this purpose, structures are printed and then electronics is inserted in the structures. There is then a need to fix the PCB which carries those electronics components to the printed structure. This is for example achieved by maintaining the components under pressure or by using screws or other fixings.

It would be desired to print directly onto a PCB. However, due to stress which builds up during the printing process, buckling of the PCB can be induced. There is therefore a need for a process which enables 3D printing over a printed circuit board.

### SUMMARY OF THE INVENTION

The invention is defined by the claims.

According to examples in accordance with an aspect of the invention, there is provided a method of manufacturing a product, comprising:

providing a printed circuit board having a surface over which a 3D structure is to be provided;

forming an adhesion layer over the surface of the printed circuit board thereby forming a first interface between the surface of the printed circuit board and the adhesion layer; and

3D printing a 3D structure over the adhesion layer thereby forming a second interface between the surface of the adhesion layer and the 3D structure,

wherein the first and/or second interface comprises a cavity structure comprising an array of cavities including cavities which have a maximum dimension in the range 1 μm to 10 mm.

This method makes use of a PCB as the substrate over which a 3D printing process may be conducted. The use of the adhesion layer provides good adhesion with the polymers used for 3D printing and also releases the stress which can be caused by printing, which could otherwise lead to buckling of the PCB.

The cavity structure has small shaped cavities forming or within a layer of a polymer which is compatible with the polymer used for 3D printing. The adhesion layer adheres both to the printed structure and to the PCB. Stress release is enabled by micro stretching of the material which either fills the cavities or is defined between the cavities. At least some of the cavities are for example micron scale. There may be multiple cavities of different sizes or they may all be the same size. By maximum size is meant the maximum linear dimension of a cavity opening (e.g. the diameter of a circular cavity opening, or the longest side of a rectangular cavity opening).

The method maintains good adhesion, avoids buckling of the PCB and enables reliable electrical contact between the electrical components and PCB conductive tracks to be maintained.

The adhesion layer may be printed. Thus, it may be considered to be part of the overall 3D printing process.

The method may further comprise providing one or more components over conductive tracks of the printed circuit board before forming the adhesion layer. The adhesion layer for example has openings over the one or more components. The adhesion layer thus does not affect the quality of the electrical connections between PCB tracks and electrical components.

The one or more components for example comprise one or more of:

an LED;

a laser diode;

passive electronic components; and

an integrated circuit.

In some cases, the 3D printed structure may thus comprise an optical element for shaping, steering or otherwise manipulating the optical output of a light source. This provides a low cost integrated light source and optics module.

The printed circuit board may comprise:

a reflective upper surface; and/or

an adhesion promoting layer.

The reflective upper surface is of particular interest for a lighting module, such as an LED module to improve the light efficiency. The adhesion promoting layer is of general interest, to improve the overall structural integrity.

In a first set of examples, the method comprises providing the surface of the printed circuit board with an array of cavities, such that the first interface (between the printed circuit board and the adhesion layer) comprises a cavity structure. The adhesion layer then fills the cavities to form a stress releasing interconnection.

In a second set of examples, the method comprises providing the adhesion layer as a discontinuous grid or pillar layer, such that the second interface (between the adhesion layer and the 3D printed structure) comprises a cavity structure formed by the grid or pillar layer. The cavity structure is then provided over the printed circuit board rather than being formed within the surface of the printed circuit board. The grid or pillar structure defines a set of openings (i.e. cavities) which are subsequently filled by the 3D printing.

The grid or pillar layer is chemically or physically attached to the PCB. The cavities enlarge the surface area of the interface between the adhesion layer and the 3D printing and hence improve the adhesion. The adhesion layer is for example more complaint than the 3D printed structure above.

When the first interface comprises the cavity structure, the cavities for example each have a maximum dimension in the range 10 μm to 0.2 mm, for example 50 μm to 0.1 mm.

When the second interface comprises the cavity structure (for example when the adhesion layer is a grid or pillar structure) the cavities may each have a maximum dimension in the range 100 μm to 10 mm.

Thus, in some examples, there are micron scale feature sizes sufficiently small for providing good adhesion as well as sufficiently large to enable local deformations to take place which achieve stress release.

Examples in accordance with another aspect of the invention provide a 3D printed product, comprising:

a printed circuit board having a surface;

an adhesion layer over the surface of the printed circuit board with a first interface between the surface of the printed circuit board and the adhesion layer; and

a 3D printed 3D structure over the adhesion layer with a second interface between the surface of the adhesion layer and the 3D structure,

wherein the first and/or second interface comprises a cavity structure comprising an array of cavities including cavities which have a maximum dimension in the range 1 μm to 10 mm.

This product integrates a 3D printed component over a printed circuit board, and prevents internal stresses caused by the 3D printing process from damaging the printed circuit board.

One or more components are for example provided over conductive tracks of the printed circuit board, and present in openings of the adhesion layer. The one or more components for example comprise one or more of:

an LED;

a laser diode;

passive electronic components; and

an integrated circuit.

The printed circuit board may comprise:

a reflective upper surface; and/or

an adhesion promoting layer.

In one example, the surface of the printed circuit board comprises an array of cavities, such that the first interface comprises a cavity structure. This may form a mechanical interlocking with the adhesion layer, for example by having cavities which include an undercut beneath the surface. In another example, the adhesion layer comprises a grid or pillar layer, such that the second interface comprises a cavity structure formed by the grid or pillar layer.

### BRIEF DESCRIPTION OF THE DRAWINGS

Examples of the invention will now be described in detail with reference to the accompanying drawings, in which:

FIG. 1 shows a fused deposition modeling printer;

FIG. 2 shows a method in which 3D printed can be performed directly onto a PCB;

FIG. 3 shows an example in which an adhesive layer comprises a polymer which is attached to a PCB;

FIG. 4 schematically shows the warping effect whereby the base of a 3D printed object becomes curved due to stress created during the 3D printing;

FIG. 5 shows various possible cavity shapes and arrangements; and

FIG. 6 shows various ways to arrange the cavities over the printed circuit board area.

### DETAILED DESCRIPTION OF THE EMBODIMENTS

The invention provides a product and a method of manufacturing a product, in which a 3D structure is printed over a printed circuit board (PCB). An adhesion layer is provided between them. One of the interfaces to the adhesion layer comprises a cavity structure. This improves adhesion and releases stress build up in the printed circuit board.

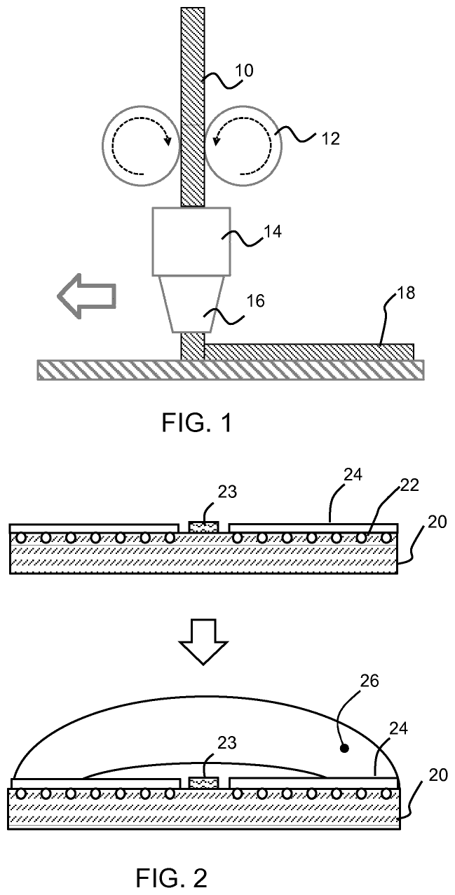

FIG. 1 is used to explain the operation of a fused deposition modeling printer.

A filament 10 is passed between a pair of driver wheels 12 to a printer head 14 having an output nozzle 16. A layer 18 of the material is deposited while in a high viscosity liquid state, which then cools and cures. A 3D structure is built up as a sequence of layer patterns.

FIG. 2 shows a method in which 3D printing can be performed directly onto a PCB.

The printed circuit board 20 has an array of cavities 22 formed in an upper surface. The cavities may be formed by conventional PCB manufacturing processes, such as drilling, etching or punching. Drilling is a mechanical process typically used for making vias (micro vias). This process is relatively low cost because it can be fully automated. Etching is also low cost but may for example only be used to form cavities in the copper portions of the printed circuit. Punching is suitable for larger dimensions (for example from 0.5 mm diameter). Other processes may also be used, such as laser scribing.

The cavities are for example formed after printing the circuit board tracks and before mounting the components. However, it is also possible to form the cavities as part of the 3D printing process, i.e. after component placement on the PCB.

In a conventional PCB manufacture process, a drilling step takes place half-way through the process. The process comprises laminating a copper layer on the bare substrate, etching the tracks, then drilling to making vias etc. Cavities may be formed at this stage. A second plating layer is then provided, for example for plating the inner walls of the drilled vias. The board is then completed with a lacquer and solder resist. The board is then ready for population with components.

The resulting PCB has conductive tracks and one or more components 23 formed over the conductive tracks. These are present before forming the adhesion layer. Thus the PCB is fully formed with all components mounted before the printing process (printing of the adhesion layer and 3D printing).

The components for example comprise one or more LEDs or laser diodes, but the invention is of more general applicability.

The PCB is covered by an adhesion layer 24. This provides good adhesion with the polymers used for 3D printing, and also releases the stress which can be caused by printing leading to buckling of the PCB. The adhesion layer for example has openings over the components and optionally also over the conductive tracks. Similarly, the cavities are provided outside the areas where there are conductive tracks and components.

The adhesion layer is formed using a polymer which is compatible with the polymer used for 3D printing. The adhesion layer 24 may itself be 3D printed.

The adhesion layer may only just fill the cavities, so that the first layer of the 3D printing process is in contact with the PCB surface and with the adhesion layer portions in the cavities. Alternatively, the adhesion layer may include a continuous layer over the cavities, as shown in FIG. 2.

The thickness of this continuous layer may for example be in the 10 μm to 1000 μm.

The resulting structure is shown in the top of FIG. 2.

The 3D printing process then creates a 3D structure 26 over the top as shown in the bottom of FIG. 2. The adhesion layer 24 adheres both to the 3D structure printed over the top and to the PCB. The stress release can happen by micro-stretching of the polymer of the adhesion layer out of the cavities.

In this case, the 3D printed structure may comprise an optical element for shaping, steering or otherwise manipulating the optical output of the LED or laser diode. This provides a low cost integrated light source and optics module.

In this example, there is a first interface between the adhesion layer and the PCB which forms a cavity structure. The cavities for example have a maximum dimension in the range 1 μm to 0.5 mm.

There is a second interface between the adhesion layer 24 and the 3D structure 26. This may instead be used to define the cavity structure.

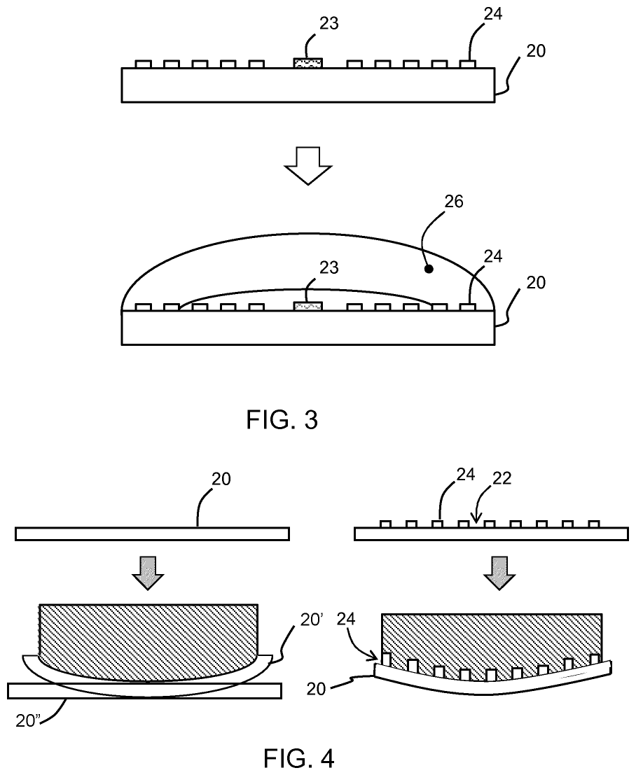

FIG. 3 shows an example in which the adhesive layer 24 comprises a polymer layer which is attached to the PCB 20 (with no cavities in the PCB surface). The polymer is attached to the PCB at discrete points because it has a grid or pillar structure, having openings formed between webs or spaces between pillars. This enables stress release and avoiding buckling. In this way buckling of the PCB can be avoided.

The grid or pillar layer may be any discontinuous layer, thereby providing discrete attachment points, such as pillars as shown in FIG. 3, where the polymer is attached to the PCB. These attachment points may be disconnected from each other.

For a pillar structure, the size (in the plane of the PCB) of pillars may be 10 μm to 5 mm with a spacing between pillars of 100 μm to 10 mm. The spaces between the attachment points function as cavities.

The polymer may attach to the PCB using a chemical bond such as an epoxy bond or acrylate groups reacting or hydrogen bonding, or van der Waals interaction.

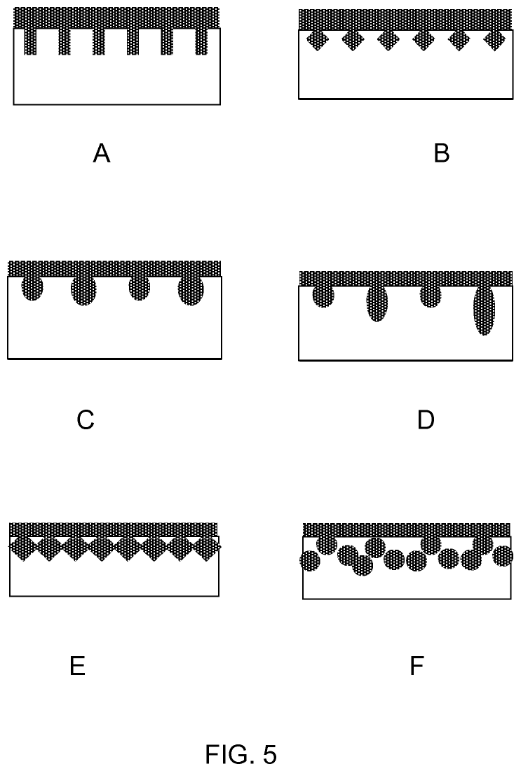

FIG. 4 schematically shows the warping or delamination effect whereby the base of a 3D printed object becomes curved due to stress created during the 3D printing. When attached to a PCB 20 it tries to induce curvature in the PCB as shown in the left image to form the shape 20′ or else delamination results as shown by shape 20″ because of shrinkage in the print. Delamination is avoided and the curvature is reduced by attaching the printed structure partially to the PCB by means of an interface with a cavity structure 24 as described above.

FIG. 4 shows the use of a pillar layer as in FIG. 3. In this case, as shown in the right image (exaggerated), the polymer adhesion layer makes better adhesion between PCB and printed top. Without the adhesion layer there is a large chance of delamination. With the cavities, the adhesion is better and the PCB keeps the printed structure flatter. The resulting buckling radius of the right sketch is thus larger than the delaminated alternative without the cavities.

FIGS. 2 and 3 show different ways of implementing the cavity interface. In one approach, the adhesion layer fills the cavities to from a semi-flexible bond, and in another approach the adhesion is between the cavities, and the cavities are defined by openings or spaces within a grid or pillar structure. They then remain empty of the adhesion layer material, which forms the structure between the pores.

The polymer of the adhesion layer and the polymer used for 3D printing are preferably the same type of material. For example, thermoplastic materials which can be used include but are not limited to thermoplastics ABS, ABSi, polyphenylsulfone (PPSF), polycarbonate (PC), polyurethane (TPU) and Ultem 9085.

For the example of a cavity structure formed in the surface of the printed circuit board (outside the components and conductor tracks), there are various possible cavity shapes and arrangements as shown in FIG. 5.

FIG. 5A shows cavities defined by pillars which extend perpendicularly into the surface of the printed circuit board. They may have a circular cross section (i.e. the shape from above) but other shapes are possible.

Alternative designs provide a cavity shape with an undercut so that the cavity forms a mechanical interlocking.

FIG. 5B shows diamond shaped cavities. They may be cylindrical (with a diamond shaped cross section) or they may be in the form of tilted cubic cavities.

FIG. 5C shows circular or oval shaped cavities. They may be cylindrical (with a circular or elliptical cross section) or they may be in the form of spherical cavities. As shown in FIG. 5C, different cavities may have different sizes. Furthermore, as shown in FIG. 5D, different cavities may have different shapes.

The cavities may be connected to form a layer beneath the surface of the printed circuit board, as shown in FIG. 5E, and there may be multiple layers of cavities as shown in FIG. 5F.

There are also various ways to arrange the cavities over the printed circuit board area.

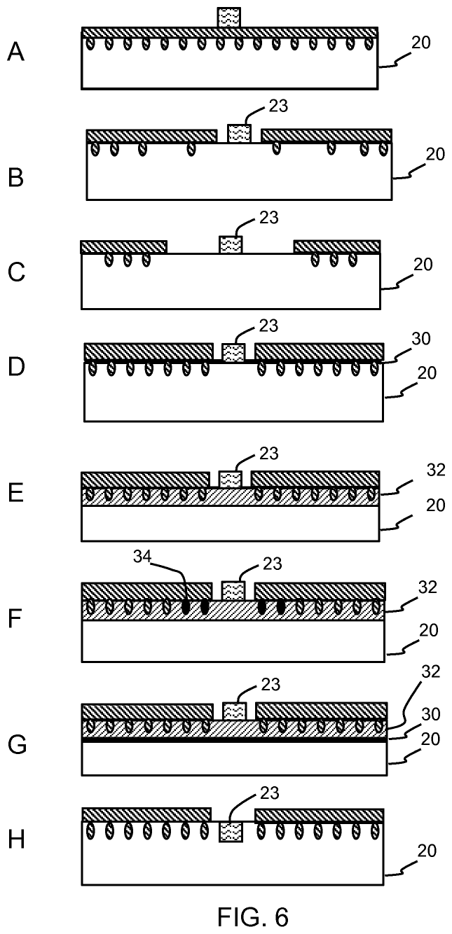

FIG. 6A shows a general idea in which the cavities can be distributed over the complete surface of the PCB, including beneath the components 23 carried by the PCB.

The conductive tracks are also covered by the adhesion layer, and the cavities may be formed in both the conductive and non-conductive parts of the PCB.

As mentioned above, the components and tracks may instead located in openings of the adhesion layer, i.e. the adhesion layer is formed as a patterned layer which extends around the components and conductive tracks. The adhesion layer is applied after the components placement.

FIG. 6B shows that the cavities may be distributed with different densities in different areas, for example with higher density away from the components. As shown in FIG. 6C, the cavities may be formed at specific areas only of the PCB, for example with no cavities close to the position of the components.

Additional layers may be used, such as an additional layer 30 between the cavities and a continuous portion of the adhesion layer as shown in FIG. 6D. This layer 30 for example may comprise:

(i) an adhesion promoter to further improve the adhesion, or

(ii) a reflective layer to improve the reflectivity of the device; or

(iii) an elastic layer; or

(iv) a light conversion layer.

For a reflector layer, an aluminum or silver layer may be used, which can be applied by physical vapor deposition (PVD) or chemical vapor deposition (CVD). Alternatively, the additional layer 30 may be a reflective coating such as a silicone coating comprising Al₂O₃, TiO₂ and/or BaSO₄ particles.

The reflectivity in the visible part of the spectrum is for example made to be above 80%, more preferably above 90%, most preferably above 95%.

An elastic may be used layer to provide flexibility to allow for shrinkage of the 3D printed structure.

A light conversion layer may be used to form part of the function of the LED, such as a layer comprising an inorganic phosphor, organic phosphor and/or quantum dots or rods. By way of example, a bottom emitting LED may be provided over the light conversion layer, so that the light output is directed through the light conversion layer.

Thus, in some examples, the additional layer 30 may be provided around the components, and in other examples, the component may sit over the additional layer. In the latter case, the additional layer is provided by the PCB supplier.

FIGS. 6E to 6G show the use of a discontinuous grid or pillar layer over the PCB 20.

FIG. 6E shows a variation in which the cavities are formed in a reflective layer 32 over which the adhesion layer is provided.

As shown in FIG. 6F, some of the cavities may be filed with a highly reflective material 34 instead of being filled by the adhesion layer. The reflective parts are for example in close proximity to the LEDs.

FIG. 6G shows the combination of an adhesion layer 30 (as in FIG. 6D) and a reflective layer 32 (as in FIG. 6E) which incorporates the cavities.

FIG. 6H shows an option by which the components 23 are buried in the PCB in order to provide a flat printing surface for the adhesion layer.

The cavities have typically a size in the range from 1 μm to 0.5 mm, more preferably in the range of 10 μm to 0.2 mm, most preferably in the range of 50 μm to 0.1 mm.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A method of manufacturing a product, comprising:
providing a printed circuit board having a surface over which a 3D structure is to be provided, the surface having an array of cavities formed therein, the cavities having a maximum dimension in the range of 1 μm to 10 mm;
forming an adhesion layer over the surface of the printed circuit board, wherein the cavities are filled by the adhesion layer; and
3D printing a 3D structure over the adhesion layer.

2. A method as claimed in claim 1, comprising printing the adhesion layer.

3. A method as claimed in claim 1, further comprising providing one or more components over conductive tracks of the printed circuit board before forming the adhesion layer.

4. A method as claimed in claim 3, wherein the adhesion layer has openings over the one or more components.

5. A method as claimed in claim 3, wherein the one or more components comprise one or more of:
an LED;
a laser diode;
passive electronic components; and
an integrated circuit.

6. A method as claimed in claim 1, wherein the printed circuit board comprises:
a reflective upper surface; and/or
an adhesion promoting layer.

7. (canceled)

8. A method as claimed in claim 1, wherein the cavities each have a maximum dimension in the range of 10 μm to 0.2 mm.

9. A 3D printed product, comprising:
a printed circuit board having a surface, the surface having an array of cavities formed therein, the cavities having a maximum dimension in the range of 1 μm to 10 mm;
an adhesion layer over the surface, wherein the cavities are filled by the adhesion layer; and
a 3D printed 3D structure over the adhesion layer.

10. A 3D printed product as claimed in claim 9, further comprising one or more components over conductive tracks of the printed circuit board present in openings of the adhesion layer.

11. A 3D printed product as claimed in claimed 10, wherein the one or more components comprise one or more of:
an LED;
a laser diode;
passive electronic components; and
an integrated circuit.

12. A 3D printed product as claimed in claim 9, wherein the printed circuit board comprises:
a reflective upper surface; and/or
an adhesion promoting layer.

13. (canceled)

14. A 3D printed product as claimed in claim 1, wherein the array of cavities forms a mechanical interlocking with the adhesion layer.

15. (canceled)
